(19) United States
(12) Patent Application Publication
(10) Pub. No.: US 2025/0338959 A1
(43) Pub. Date: Nov. 6, 2025

(54) SLIDE RAIL BRACKET AND FASTENING DEVICE USING THE SAME

(71) Applicant: LITE-ON TECHNOLOGY CORPORATION, Taipei (TW)

(72) Inventor: Qi-Hong YANG, Taipei (TW)

(21) Appl. No.: 18/986,802

(22) Filed: Dec. 19, 2024

Related U.S. Application Data
(60) Provisional application No. 63/641,967, filed on May 3, 2024.

(30) Foreign Application Priority Data
Aug. 6, 2024 (CN) 202411069518.0

(51) Int. Cl. A47B 88/423; A47B 96/06

(52) U.S. Cl. CPC A47B 88/423; A47B 96/06; A47B 2210/09

(57) ABSTRACT

A slide rail bracket including a fixing member and a sliding member is provided. The fixing member has a first fixing end and a second fixing end. The sliding member is disposed on the fixing member and slides along a sliding direction relative to the fixing member. The sliding member has a first support arm located in a vertical projection direction and a second support arm located in a horizontal projection direction. The first fixing end, the second fixing end and the second support arm are coplanar in the sliding direction, and the terminal of the sliding member has a stopper for abutting against the second fixing end.

### SLIDE RAIL BRACKET AND FASTENING DEVICE USING THE SAME

This application claims the benefits of U.S. provisional application No. 63/641,967, filed May 3, 2024 and People's Republic of China application Serial No. 202411069518.0, filed Aug. 6, 2024, the subject matters of which are incorporated herein by reference.

### BACKGROUND OF THE INVENTION

### Field of the Invention

The invention relates in general to a slide rail bracket and a fastening device using the same.

### Description of the Related Art

The server fixing bracket is used for the installation of a server on a rack. Furthermore, the server fixing bracket is slidable relative to the rack, allowing the server to be slide into or out of the rack. However, while such slidable type of server fixing bracket facilitates easier installation for the installer, but it requires a greater thickness compared to static server racks. Therefore, usable space of the server inside the rack is reduced.

### SUMMARY OF THE INVENTION

The invention is directed to a slide rail bracket and a fastening device using the same, which are easy to install and occupy less space.

According to one embodiment of the present invention, a slide rail bracket is provided. The slide rail bracket includes a fixing member and a sliding member. The fixing member has a first fixing end and a second fixing end. The sliding member is disposed on the fixing member and slides along a sliding direction relative to the fixing member. The sliding member has a first support arm located in a vertical projection direction and a second support arm located in a horizontal projection direction. The first fixing end, the second fixing end and the second support arm are coplanar in the sliding direction, and the terminal of the sliding member has a stopper for abutting against the second fixing end.

According to another embodiment of the present invention, a fastening device is provided. The fastening device includes a rack and a slide rail bracket. The slide rail bracket is disposed in the rack, and the slide rail bracket slides into or out of the rack. The slide rail bracket includes a fixing member and a sliding member. The fixing member has a first fixing end and a second fixing end. The sliding member is disposed on the fixing member and slides along a sliding direction relative to the fixing member. The sliding member has a first support arm located in a vertical projection direction and a second support arm located in a horizontal projection direction. The first fixing end, the second fixing end and the second support arm are coplanar in the sliding direction, and the terminal of the sliding member has a stopper for abutting against the second fixing end.

The above and other aspects of the invention will become better understood with regard to the following detailed description of the preferred but non-limiting embodiment(s). The following description is made with reference to the accompanying drawings.

### BRIEF DESCRIPTION OF THE DRAWINGS

FIGS. 1A and 1B are schematic diagrams illustrating different perspectives of a server enclosure sliding into a rack according to an embodiment of the invention.

FIGS. 2A and 2B are schematic diagrams illustrating different perspectives of a server enclosure sliding out of a rack according to an embodiment of the invention.

FIG. 2C is a partial enlarged view of a slide rail bracket.

FIGS. 3A and 3B are schematic diagrams illustrating different perspectives of a slide rail bracket according to an embodiment of the invention.

FIG. 3C is a schematic cross-section diagram of an installation member along a line A-A.

FIGS. 4A and 4B are explosion diagrams illustrating different perspectives of a slide rail bracket.

FIGS. 5A and 5B are explosion diagrams illustrating different perspectives of a slide rail bracket according to another embodiment of the invention.

FIG. 5C is a partial enlargement and a schematic cross-section diagram of a slide rail bracket along a line B-B.

### DETAILED DESCRIPTION OF THE INVENTION

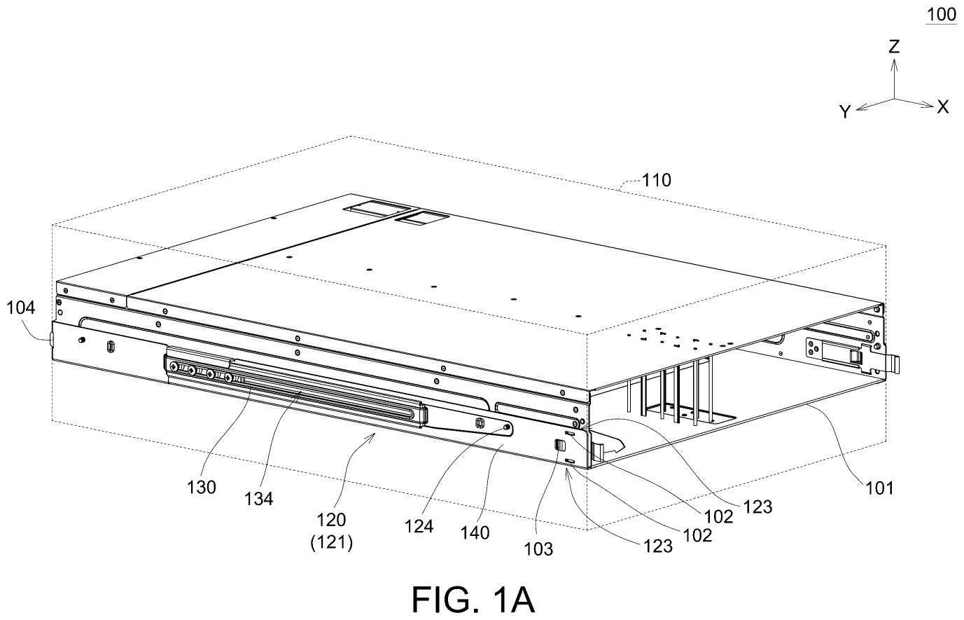

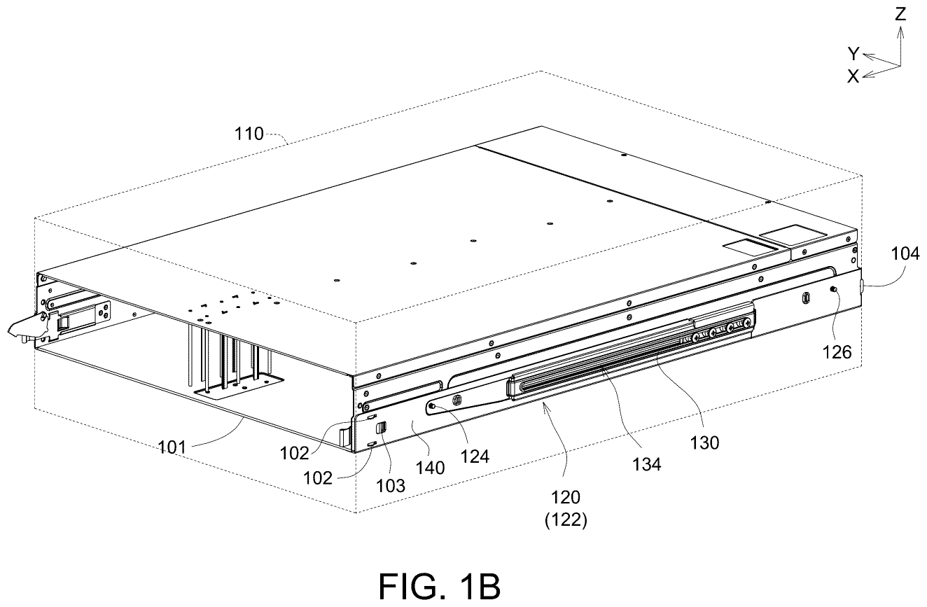

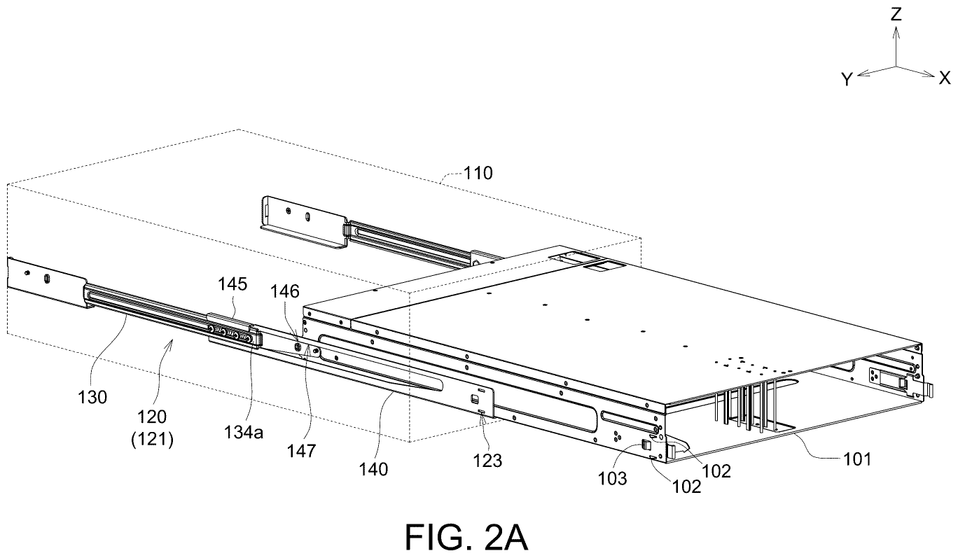

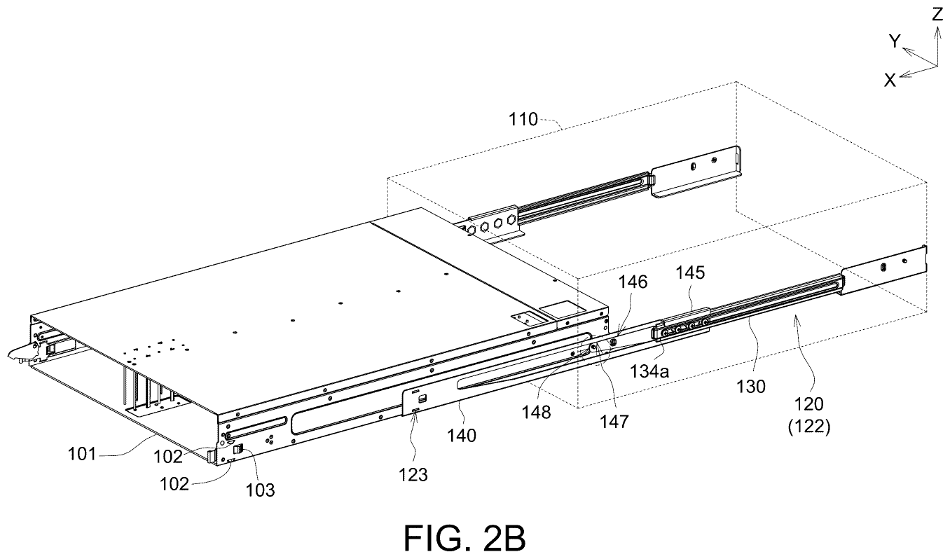

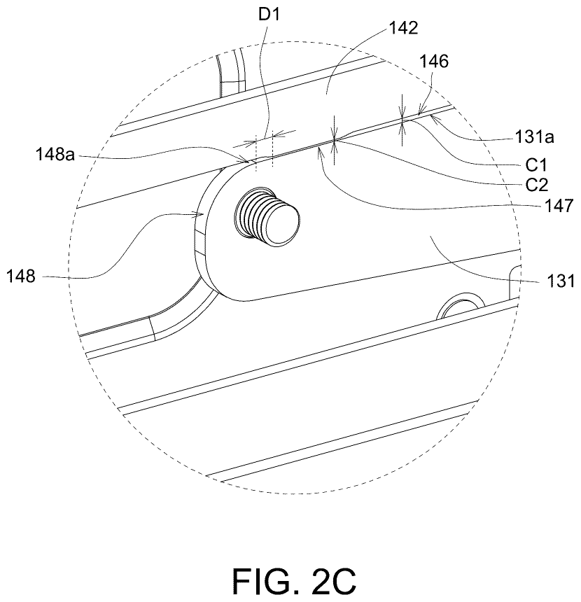

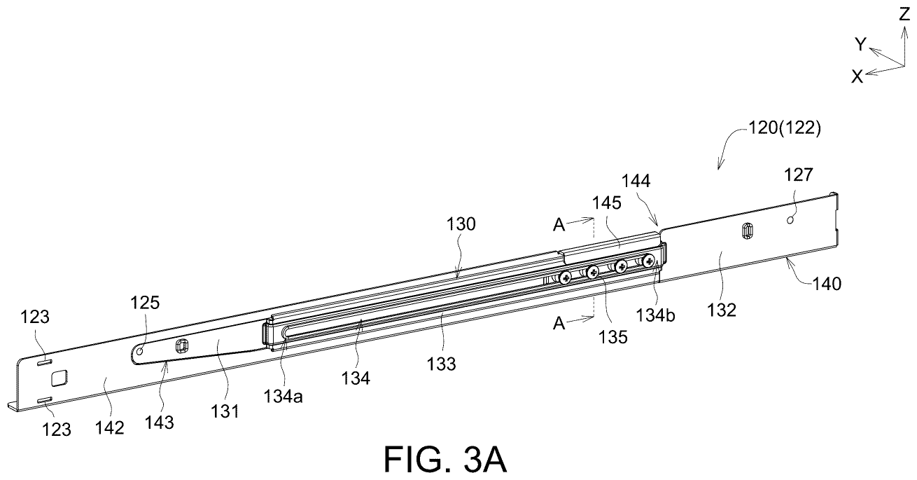

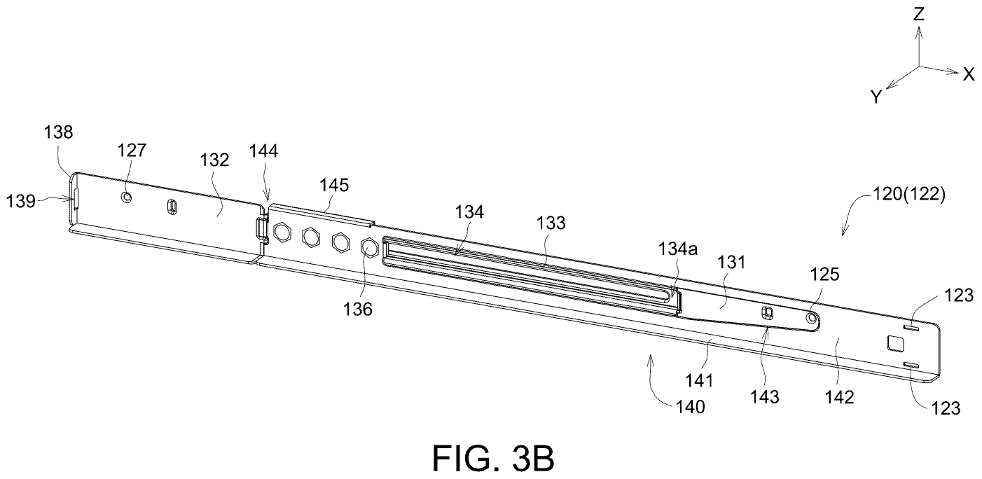

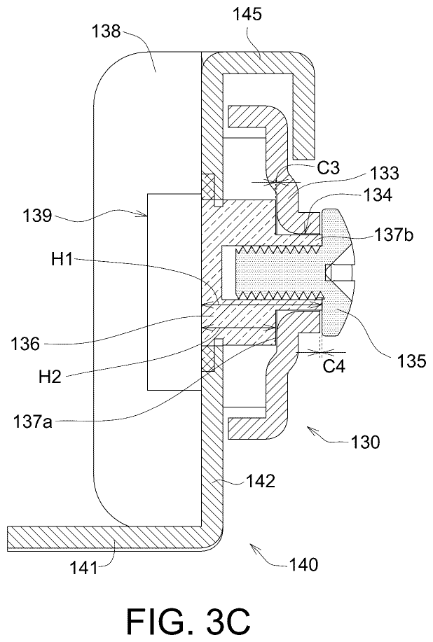

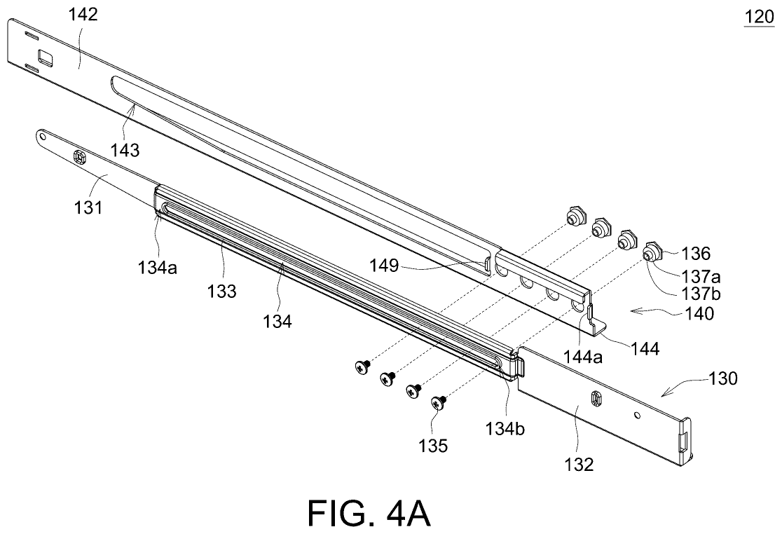

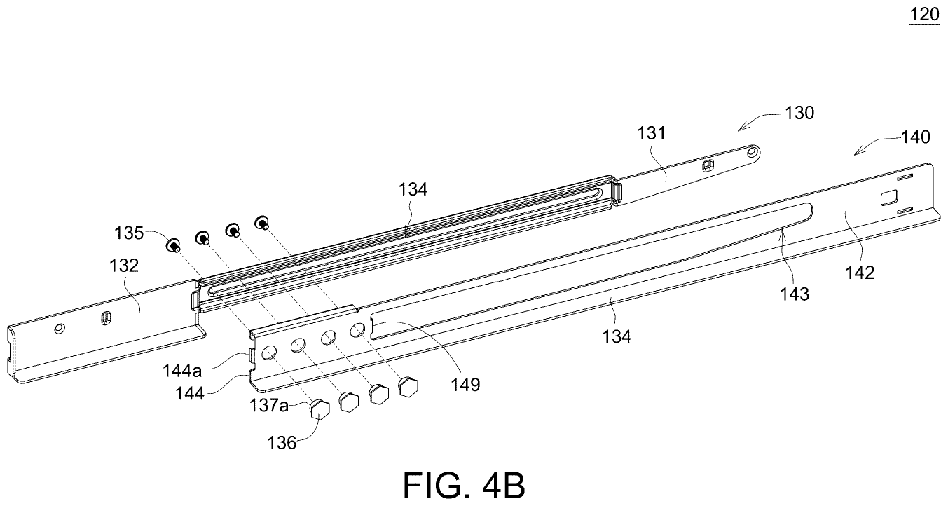

FIG. 1A to FIG. 4B, FIGS. 1A and 1B are schematic diagrams illustrating different perspectives of a server enclosure 101 sliding into a rack 110 according to an embodiment of the invention. FIGS. 2A and 2B are schematic diagrams illustrating different perspectives of a server enclosure 101 sliding out of a rack 110 according to an embodiment of the invention. FIG. 2C is a partial enlarged view of a slide rail bracket 120. FIGS. 3A and 3B are schematic diagrams illustrating different perspectives of a slide rail bracket 120 according to an embodiment of the invention. FIG. 3C is a schematic cross-section diagram of an installation member along a line A-A. FIGS. 4A and 4B are exploded schematic diagrams showing different perspectives of the slide rail bracket 120.

In an embodiment, the fastening device 100 can be a large-sized server chassis. The fastening device 100 includes a rack 110 and a slide rail bracket 120. The slide rail bracket 120 is disposed in the rack 110 and slides relative to the rack 110. The slide rail bracket 120 serves to facilitate the installation of a server enclosure 101 in the rack 110, so that the server enclosure 101 can slide into or out of the rack 110.

As indicated in FIGS. 1A and 1B, the slide rail bracket 120 is a pair of L-shaped brackets, namely, the left bracket 121 and the right bracket 122, disposed on two opposite sides of the interior of the rack 110 to support the server enclosure 101. Moreover, the server enclosure 101 can be engaged with the slide rail bracket 120 by using two engaging members 102 disposed on a lateral side of the server enclosure 101, so that the server enclosure 101 can be fixed on the slide rail bracket 120. The engaging member 102 can be realized by two tabs. The two tabs match two positioning members (such as positioning holes 123) on the slide rail bracket 120, so that the server enclosure 101 and the slide rail bracket 120 can be engaged with each other in at least one direction (such as the Z-axis direction) perpendicular to the sliding direction (such as the X-axis direction).

Refer to FIGS. 2A and 2B. The slide rail bracket 120 can bear the weight of the server and drive it to move outwards. When the sliding member 140 moves outwards to the first stopping portion 134a, the sliding member 140 is completely pulled out. To pull the server enclosure 101 out of the rack 110, the user only needs to pull the server enclosure 101 out of the rack 110 and press a releasing member 103 disposed on a lateral side of the server enclosure 101 to release the engagement between the engaging member 102 and two positioning members (such as positioning holes 123) of the slide rail bracket 120. The server will then be uninstalled. The releasing member 103 may be a spring piece. The releasing member 103 and the engaging member 102 are integrally formed as a spring member and positioned on a lateral side of the server enclosure 101 for the user to press the releasing member 103 and release the engagement.

Refer to FIGS. 3A and 3B, for the sake of explanation, FIGS. 3A and 3B only illustrate one of the slide rail brackets 120 (such as the right bracket 122). The left bracket 121 and the right bracket 122 form a symmetric structure, and the explanations are not further described here. The slide rail bracket 120 includes a fixing member 130 and a sliding member 140. The fixing member 130 has a first fixing end 131 and a second fixing end 132. The first fixing end 131 is located at the front end of the fixing member 130 (close to the extended side of the server enclosure 101), and the second fixing end 132 is located at the rear end of the fixing member 130. Besides, the fixing member 130 further has a sliding member installation portion 133 interposed between the first fixing end 131 and the second fixing end 132. The sliding member installation portion 133 serves to facilitate the disposition of the sliding member 140 on the fixing member 130 and allows the sliding member 140 to slide along a sliding direction relative to the fixing member 130.

Refer to FIGS. 3A and 3B, to reduce the overall thickness of the fixing member 130 and the sliding member 140, the sliding member 140 is designed as an L-shaped bracket. The sliding member 140 can be coplanar with a part of the fixing member 130 to form a slide rail bracket 120 with a smaller size. In an embodiment, the sliding member 140 (L-shaped bracket) includes a first support arm 141 located in a vertical projection direction (such as the Z-axis direction) and a second support arm 142 located in a horizontal projection direction (such as the Y-axis direction). The first support arm 141 and the second support arm 142 substantially are perpendicular to each other and form an L-shaped bracket. Besides, the first fixing end 131 of the fixing member 130 can be disposed in a groove 143 of the second support arm 142, so that the first fixing end 131 overlap the second support arm 142 in a vertical projection direction (such as the Z-axis direction). That is, the first fixing end 131 and the second support arm 142 are coplanar, and the second fixing end 132 of the fixing member 130 can extend backwards from the terminal 144 of the second support arm 142, so that the first fixing end 131, the second fixing end 132 and the second support arm 142 of the fixing member 130 are coplanar in the sliding direction of the sliding member 140 (such as the X-axis direction).

In an embodiment, the fixing member 130 can be locked on the sliding member 140 using screws 124, 126. The screw 124 passes through the screw hole 125 of the first fixing end 131 to lock the first fixing end 131 on the front side of the rack 110 (FIG. 1B), and the screw 126 passes through the screw hole 127 of the second fixing end 132 to lock the second fixing end 132 on the rear side of the rack 110 (FIG. 1B). Additionally, the sliding member installation portion 133 includes a slide groove 134 and at least one installation member (four are illustrated in the diagram). The slide groove 134 extends along the sliding direction (such as the X-axis direction), and the front end and the rear end of the slide groove 134 respectively have a first stopping portion 134a and a second stopping portion 134b for limiting the sliding distance of the sliding member 140 relative to the fixing member 130. Referring to FIGS. 4A and 4B, the installation member includes a screw 135 and a screw socket 136. The screw 135 can pass through the slide groove 134 and is fixed in the screw socket 136. The screw socket 136 is disposed on the sliding member 140 and extends a platform 137a towards the fixing member 130 (FIG. 3C).

Referring to FIG. 3C, a schematic cross-section diagram of an installation member along a line A-A (FIG. 3A) is shown. The installation member serves to facilitate the disposition of the sliding member 140 on the sliding member installation portion 133. The screw socket 136 has a platform 137a and a convex pillar 137b. The convex pillar 137b is protruded from the platform 137a and extends to the slide groove 134. The height H1 of the convex pillar 137b is greater than the height H2 of the platform 137a, and the height difference (i.e., H2−H1) between the height of the platform 137a and the height of the convex pillar 137b is greater than the depth of the slide groove 134. The screw 135 can be locked on the convex pillar 137. Moreover, since the screw 135 and the platform 137a do not contact two opposite surfaces of the sliding member installation portion 133, the screw 135 and the sliding member installation portion 133 are separated by a gap C4, and the platform 137a and the sliding member installation portion 133 are separated by another gap C3. Thus, the sliding member 140 and the fixing member 130 will not generate sliding friction, which would otherwise affect the sliding of the sliding member 140.

Refer to FIGS. 3A and 3B. The first fixing end 131, the second fixing end 132 and the sliding member installation portion 133 of the fixing member 130 are not coplanar in the sliding direction (such as X-axis direction) of the sliding member 140. That is, the sliding member installation portion 133 and the sliding member 140 are not coplanar. The sliding member 140 can abut against the sliding member installation portion 133 and slide thereon through a slide rail rack 145. In an embodiment, the sliding member installation portion 133 is located outside the sliding member 140 (i.e., the side close to the server enclosure 101), the first fixing end 131 is bent and connected to one end of the sliding member installation portion 133 and extend to the front end, and the second fixing end 132 is bent and connected to another end of the sliding member installation portion 133 and extend to the rear end. Thus, the fixing member 130 substantially includes a sliding member installation portion 133 whose central part is not coplanar, and a first fixing end 131 and a second fixing end 132 are bent and extended from the sliding member installation portion 133 whose central part is not coplanar towards the two ends of the sliding member installation portion 133 (i.e., the front end and the rear end). That is, the sliding member installation portion 133 is formed by the first fixing end 131 and the second fixing end 132 bending towards the outside of the fixing member 130.

Refer to FIGS. 3A and 3B. The second fixing end 132 of the fixing member 130 further includes a rear stopping tab 138 formed by bending the bottom side of the second fixing end 132 inwardly. Refer to FIGS. 4A and 4B, the terminal 144 of the sliding member 140 may further include a stopper 144a formed by bending a lateral side of the second support arm 142 outwardly and used for abutting against the second fixing end 132. Besides, the terminal of the groove 143 of the sliding member 140 may further include a stopper 149 formed by bending a lateral side of the second support arm 142 outwardly. When the sliding member 140 slides forwards and reaches the first stopping portion 134a, the stopper 149 abuts against the first fixing end 131.

As indicated in FIG. 1A, when the installer moves the server enclosure 101 towards the interior of the rack 110, the enclosure rear wall of the server enclosure 101 and the rear stopping tab 138 (FIG. 3B) interfere with each other, so that the server enclosure 101 and the fixing member 130 are mutually engaged in at least one direction (such as the Z-axis direction) perpendicular to the sliding direction (such as the X-axis direction). In an embodiment, the enclosure rear wall of the server enclosure 101 has a protruding tab 104. The protruded tab 104 matches a hole 139 of the rear stopping tab 138 (FIG. 3B). When the installer moves the server enclosure 101 towards the interior of the rack 110, the rear stopping tab 138 can limit the backward movement of the server enclosure 101. Furthermore, the protruding tab 104 can be inserted into the hole 139 of the rear stopping tab 138 to complete the positioning of the server enclosure 101.

Refer to FIGS. 2A and 2B. The sliding member 140 can bear the weight of the server enclosure 101 and drive the server enclosure 101 to move outwards. When the sliding member 140 moves outwards and reaches the first stopping portion 134a, the sliding member 140 is completely pulled out. Meanwhile, to avoid the server pressing downward with its weight and making the second support arm 142 of the sliding member 140 completely abut against the top surface 131a of the first fixing end 131 of the fixing member 130 (FIG. 2C), a flange 147 is formed between the groove inner surface 146 of the second support arm 142 and the top surface 131a of the first fixing end 131 (referring to a partial enlarged view of FIG. 2C). The flange 147 has a length of about 1 cm and height of about 0.3 cm. The dimensions can be adjusted according to actual situations. Besides, a first gap C1 of about 0.05 cm is formed between the groove inner surface 146 of the second support arm 142 and the top surface 131a of the first fixing end 13. A second gap C2 of about 0.02 cm is formed between the lower surface of the flange 147 and the top surface 131a of the first fixing end 131. The second gap C2 is less than the first gap C1. When the server enclosure 101 is pressed down, the lower surface of the flange 147 slides in contact with the top surface 131a of the first fixing end 131. This prevents the second support arm 142 from fully resting against the top surface 131a of the first fixing end 131. In other words, it avoids the lower surface of the second support arm 142 from completely contacting the top surface 131a, thereby improving the issue of excessive friction causing the server enclosure 101 to get stuck during sliding.

Referring to FIG. 2C, a partial enlarged view of a slide rail bracket 120 is shown. The front edge of the first fixing end 131 of the fixing member 130 has an arc surface 148. The arc surface 148 has a starting point 148a on the top surface 131a of the first fixing end 131. An arc angle is formed from the starting point 148a downwards. When the sliding member 140 is completely pulled out, the front edge of the flange 147 and the starting point 148a of the arc surface 148 are separated by a safety distance D1, to avoid affecting the support function between the sliding member 140 and the fixing member 130 being affected. The safety distance, for example, can be 0.23 cm, but still can be adjusted according to actual situations.

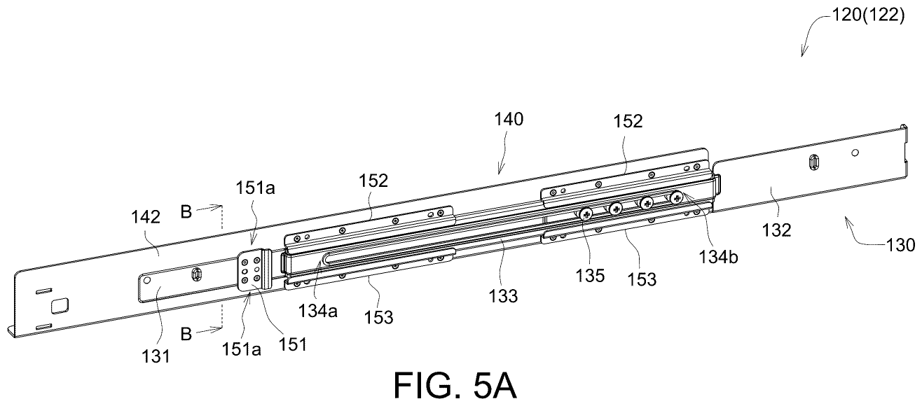

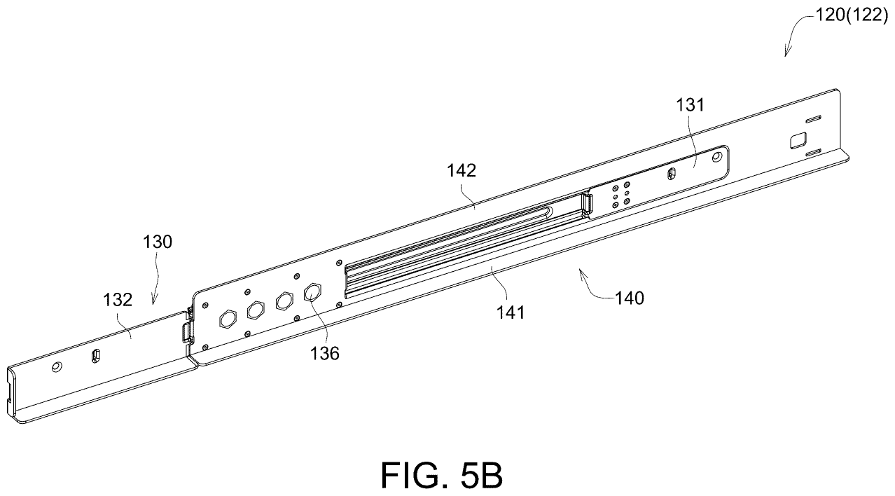

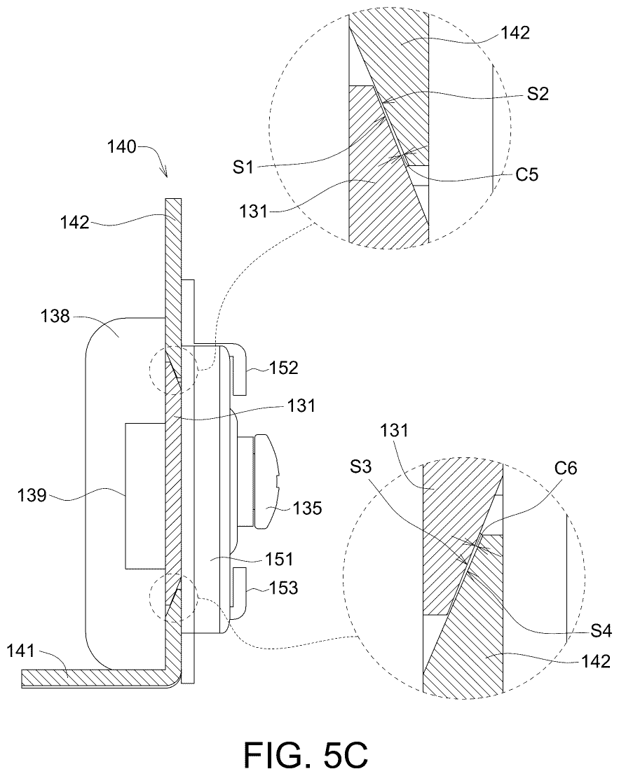

Referring to FIGS. 5A and 5B, explosion diagrams illustrating different perspectives of a slide rail bracket 120 according to another embodiment of the invention are shown. In the present embodiment, to enhance the structure of the thin sliding member 140 and avoid deformation, the back side of the sliding member 140 can be enhanced with at least one enforcement member. In an embodiment, the first enforcement member 151 is disposed on the back side of the first fixing end 131 of the fixing member 130. The first enforcement member 151 forms at least one holding portion 151a by extending from the back side of the first fixing end 131 of the fixing member 130 towards the back side of the second support arm 142 of the sliding member 140. A predetermined gap, such as 0.02 cm, is formed between the holding portion 151a and the back side of the second support arm 142 of the sliding member 140. When the sliding member 140 is completely pulled out, the sliding member 140 is pressed downwards by the weight of the server, making the holding portion 151a contact the back side of the second support arm 142 of the sliding member 140 and support the sliding member 140. Besides, the second enforcement member 152 and the third enforcement member 153 are disposed on the back side of the second support arm 142 of the sliding member 140 and are respectively located on the upper side and the lower side of the sliding member installation portion 133. When the sliding member 140 is completely pulled out, the second enforcement member 152 and the third enforcement member 153 respectively abut against the upper surface and the lower surface of the sliding member installation portion 133 to offset the deformation of the sliding member 140 caused by the weight of the server.

Referring to FIG. 5C, a partial enlargement and a schematic cross-section diagram of a slide rail bracket 120 along a line B-B are shown. To reduce the friction, the upper lateral edge of the first fixing end 131 of the fixing member 130 has a first bevel S1, and the groove inner surface 146 of the second support arm 142 of the sliding member 140 has a second bevel S2, wherein the first bevel S1 and the second bevel S2 are opposite to each other and the first bevel S1 and are separated by a first interval C5. Besides, the lower lateral edge of the first fixing end 131 of the fixing member 130 has a third bevel S3, and the groove inner surface 146 of the second support arm 142 of the sliding member 140 has a fourth bevel S4, wherein the third bevel S3 and the fourth bevel S4 are opposite to each other and are separated by a second interval C6. In an embodiment, the first bevel S1 and the second bevel S2 are not parallel to each other, so that the first interval C5 has unequal width in the direction of vertical cross-section. Likewise, the third bevel S3 and the fourth bevel S4 are not parallel to each other, so that the second interval C6 has unequal width in the direction of vertical cross-section. When the server presses downwards with its weight and makes the sliding member 140 deformed, the first interval C5 and the second interval C6 with unequal width can maintain a sufficient gap between the deformed sliding member 140 and the fixing member 130 to avoid the jamming problem caused by friction.

The slide rail bracket and the fixing device described in the above embodiments of the present invention allow the server enclosure to slide out of the chassis, facilitating installation or removal of the server by the installer. Additionally, the flat slide rail bracket of the invention requires less thickness compared to conventional sliding server racks, thereby increasing the usable space within the chassis for the server enclosure.

While the invention has been described by way of example and in terms of the preferred embodiment(s), it is to be understood that the invention is not limited thereto. Based on the technical features embodiments of the present invention, a person ordinarily skilled in the art will be able to make various modifications and similar arrangements and procedures without breaching the spirit and scope of protection of the invention. Therefore, the scope of protection of the present invention should be accorded with what is defined in the appended claims.

What is claimed is:

1. A slide rail bracket, comprising:
a fixing member having a first fixing end and a second fixing end; and
a sliding member disposed on the fixing member and slidable along a sliding direction relative to the fixing member, the sliding member has a first support arm located in a vertical projection direction and a second support arm located in a horizontal projection direction, wherein the first fixing end, the second fixing end and the second support arm are coplanar in the sliding direction, and a terminal of the sliding member has a stopper for abutting against the second fixing end.

2. The slide rail bracket according to claim 1, wherein the first fixing end is disposed in a groove of the second support arm, the first fixing end and the second support arm overlap in the vertical projection direction.

3. The slide rail bracket according to claim 2, wherein a flange is formed between a groove inner surface of the second support arm and a top surface of the first fixing end, and a gap is formed between a lower surface of the flange and the top surface of the first fixing end.

4. The slide rail bracket according to claim 1, wherein the second fixing end extends backwards from a terminal of the second support arm.

5. The slide rail bracket according to claim 1, wherein the fixing member has a sliding member installation portion interposed between the first fixing end and the second fixing end for the sliding member to be disposed on the fixing member.

6. The slide rail bracket according to claim 5, wherein the sliding member installation portion comprises a slide groove and at least one installation member, the slide groove extends along the sliding direction, and a front end and a rear end of the slide groove respectively have a first stopping portion and a second stopping portion.

7. The slide rail bracket according to claim 6, wherein the installation member comprises a screw and a screw socket, and the screw passes through the slide groove and is fixed in the screw socket.

8. The slide rail bracket according to claim 7, wherein the screw socket is disposed on the sliding member and extends a platform towards the fixing member, and the platform and the fixing member are separated by a gap.

9. The slide rail bracket according to claim 5, wherein the first fixing end, the second fixing end and the sliding member installation portion are not coplanar in the sliding direction.

10. The slide rail bracket according to claim 5, further comprising at least one enforcement member disposed on a back side of the second support arm and located on at least one side of the sliding member installation portion.

11. The slide rail bracket according to claim 3, wherein an upper surface of the first fixing end is a first bevel, the groove inner surface of the second support arm has a second bevel, and the first bevel and the second bevel are opposite to each other and are separated by a first interval.

12. The slide rail bracket according to claim 11, wherein the lower surface of the first fixing end is a third bevel, the groove inner surface of the second support arm has a fourth bevel, and the third bevel and the fourth bevel are opposite to each other and are separated by second interval.

13. The slide rail bracket according to claim 12, wherein the first bevel and the second bevel are not parallel to each other, and the third bevel and the fourth bevel are not parallel to each other.

14. The slide rail bracket according to claim 1, further comprising at least one enforcement member disposed on a back side of the first fixing end of the fixing member, and the enforcement member extends from the back side of the first fixing end towards the back side of the second support arm to form at least one holding portion.

15. A fastening device, comprising:
a rack; and
the slide rail bracket according to claim 1, wherein the slide rail bracket is disposed in the rack and configured to slide into or out of the rack.
